(19) United States
(12) Patent Application Publication
(10) Pub. No.: US 2011/0297211 A1
(43) Pub. Date: Dec. 8, 2011

(54) ENCAPSULATION OF PHOTOVOLTAIC MODULE

(75) Inventor: Wei-Lun HSIAO, Taoyuan County (TW)

(73) Assignee: Du Pont Apollo Limited, Hong Kong (HK)

(21) Appl. No.: 13/151,292

(22) Filed: Jun. 2, 2011

Related U.S. Application Data
(60) Provisional application No. 61/351,933, filed on Jun. 7, 2010.

(51) Int. Cl. H01L 31/048; H01L 31/0203

(52) U.S. Cl. 136/251; 438/64; 257/E31.117

(57) ABSTRACT

Various combinations of a first encapsulant and a second encapsulant on different locations of a photovoltaic module are used to meet various requirements of optical clarity, tensile strength, waterproofness, and resistivity.

### RELATED APPLICATIONS

This application claims priority to U.S. Provisional Application Ser. No. 61/351,933, filed Jun. 7, 2010, which is herein incorporated by reference.

### BACKGROUND

1. Technical Field

The disclosure relates to photovoltaic module. More particularly, the disclosure relates to encapsulation of photovoltaic modules.

2. Description of Related Art

Since photovoltaic (PV) modules, also commonly known as solar modules or solar panels, are used outdoors, PV modules are exposed to atmospheric humidity and oxygen, which will deteriorate the performance of the PV modules. Therefore, encapsulant is used to encapsulate photovoltaic modules to protect the PV cells of the PV modules.

In present, the commonly used encapsulant includes Ethylene-vinyl acetate (EVA) and polyvinyl butyral (PVB). EVA is much cheaper and has a good optical clarity, but the waterproofness of EVA is poor. PVB has a good tensile strength, waterproofness, and optical clarity, but the resistivity is poor. Moreover, PVB is quite expensive. Hence, it is hard to use an encapsulant that is both good at the various properties above and cheap enough for encapsulating PV modules.

### SUMMARY

In this invention, the problem above is solved by using a combination of multiple kinds of encapsulant on different locations of a PV module.

According to an embodiment of this invention, the PV cells of a PV module, i.e. the interior part of the PV module, is encapsulated by a first encapsulant that has good optical clarity and moderate tensile strength. The peripheral part, which surrounds the PV cells, of the PV module is encapsulated by a second encapsulant that has good waterproofness and resistivity. Since the waterproofness of the second encapsulant is good enough, the second encapsulant does not need to contain any desiccant material.

Accordingly, various combinations of the first encapsulant and the second encapsulant can be used to protect the PV modules to give considerations on all requirements above. Moreover, more opportunities can be found to reduce the cost of encapsulating the PV modules.

It is to be understood that both the foregoing general description and the following detailed description are by examples, and are intended to provide further explanation of the invention as claimed.

### BRIEF DESCRIPTION OF THE DRAWINGS

FIG. 1 is a cross-sectional diagram of an encapsulated photovoltaic module according to an embodiment of this invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

As stated above, an encapsulant needs to have good optical clarity, tensile strength, resistivity, and waterproofness to give considerations on both to cell efficiency and protecting the PV module from being damaged by various outdoor factors, such as rains or humidity, temperature, thunders, and some other external forces. However, it is difficult to find an encapsulant to meets the multiple requirements above, let alone find a cheap encapsulant.

This invention uses a combination of multiple kinds of encapsulant on different locations of a PV module to meet the multiple requirements. Moreover, more opportunities can be found to reduce the cost of encapsulating the PV modules.

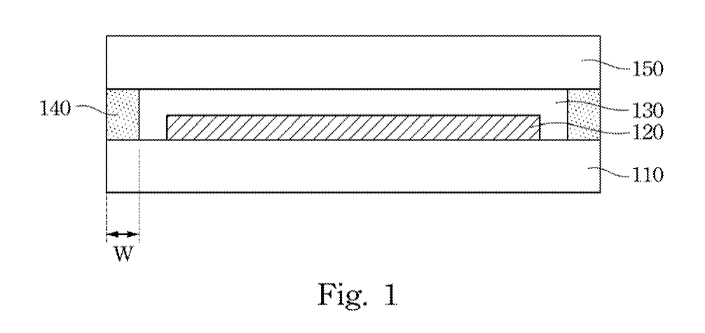

FIG. 1 is a cross-sectional diagram of an encapsulated photovoltaic module according to an embodiment of this invention. In FIG. 1, a photovoltaic (PV) cell array 120, which contains multiple PV cells, is formed on a front substrate 110. The PV cell array 120 can be formed by any available methods, such as deposition, patterning, and etching processes. The front substrate 110 is transparent to light. The material of the front substrate 110 can be glass or plastic, for example.

A first encapsulant 130 is applied on the PV cell array 120 to encapsulate the PV cell array 120. The first encapsulant 130 has good optical clarity (>90%) to permit higher light penetration rate and moderate tensile strength to protect the PV cell array 120 from being damaged by external forces. The first encapsulant 130 can be EVA or PVB, for example.

A second encapsulant 140 is applied on the peripheral region, which surrounding the PV cell array 120, of the front substrate. The second encapsulant 140 has excellent waterproofness to protect the PV cell array 120 from being damaged by water vapor in air and rains and has excellent resistivity to prevent current leakage. Accordingly, the width, W, of the second encapsulant 140 can be effectively reduced to increase the occupied area of the photovoltaic cells. Moreover, since the waterproofness of the second encapsulant is good enough, the second encapsulant does not need to contain any desiccant material.

The second encapsulant 140 can be ionomer, for example. An ionomer is a polymer that comprises repeat units of both electrically neutral repeating units and a fraction of ionized units (usually no more than 15 percent). The ionomer is good at tensile strength, waterproofness, and resistivity, but the ionomer is quite expensive.

The related properties of the above-mentioned materials are listed in the table below.

| Encapsulant | Ionomer | PVB | EVA |
|---|---|---|---|
| Optical clarity | >91% | >91% | >91% |
| Tensile strength (MPa) | 34.5 | 28.1 | 16 |
| Surface Resistivity (W) | 1.49 × 10¹⁶ | 2 × 10¹³ | 1 × 10¹⁴ |
| Volume Resistivity (W-cm) | 3.05 × 10¹⁶ | 2 × 10¹¹ | 1 × 10¹⁴ |
| Water Vapor Transmission Rate | 0.70 | 39 | 18-20 |
| (g mm/m²/day) | | | |

Finally, a back substrate 150 is laminated on the first encapsulant 130 and the second encapsulant 140 to obtain the final PV module. The back substrate 150 is transparent to light. The material of the back substrate 150 can be glass or plastic, for example.

Accordingly, various combinations of the first encapsulant and the second encapsulant can be used to protect the PV modules to give considerations on all requirements above. For example, when the first encapsulant 130 is EVA, the second encapsulant 140 can be ionomer. In another example, when the first encapsulant 130 is PVB, the second encapsulant 140 can be ionomer. Moreover, since the cheap EVA can be used to covering the PV cell array 120, and more expensive PVB or ionomer is used to only cover the peripheral part, the encapsulation cost can be greatly decreased.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, each feature disclosed is one example only of a generic series of equivalent or similar features.

What is claimed is:

1. An encapsulation of a photovoltaic module, comprising:
a first encapsulant covering a photovoltaic cell array on a front substrate, wherein the first encapsulant has good optical clarity and moderate tensile strength; and
a second encapsulant covering peripheral part of the front substrate, wherein the peripheral part surrounds the photovoltaic cell array, wherein the second encapsulant has good waterproofness and resistivity, and wherein the second encapsulant does not contain desiccant material.

2. The encapsulation of claim 1, wherein the first encapsulant is ethylene-vinyl acetate or polyvinyl butyral.

3. The encapsulation of claim 1, wherein the second encapsulant is ionomer.

4. A photovoltaic module, comprising:
a front substrate;
a photovoltaic cell array on the front substrate;
a first encapsulant covering the photovoltaic cell array, wherein the first encapsulant has good optical clarity and moderate tensile strength;
a second encapsulant covering peripheral part of the front substrate, wherein the peripheral part surrounds the photovoltaic cell array, wherein the second encapsulant has good waterproofness and resistivity, and wherein the second encapsulant does not contain desiccant material; and
a back substrate covering the first encapsulant and the second encapsulant.

5. The photovoltaic module of claim 4, wherein the first encapsulant is ethylene-vinyl acetate or polyvinyl butyral.

6. The photovoltaic module of claim 4, wherein the second encapsulant is ionomer.

7. The photovoltaic module of claim 4, wherein the front substrate is glass or plastic.

8. The photovoltaic module of claim 4, wherein the back substrate is glass or plastic.

9. A method of encapsulating a photovoltaic module, comprising:
applying a first encapsulant onto a photovoltaic cell array on a front substrate, wherein the first encapsulant has good optical clarity and moderate tensile strength;
applying a second encapsulant onto peripheral part of the front substrate, wherein the peripheral part surrounds the photovoltaic cell array, wherein the second encapsulant has good waterproofness and resistivity, and wherein the second encapsulant does not contain desiccant material; and
laminating a back substrate on the first encapsulant and the second encapsulant.

10. The method of claim 9, wherein the first encapsulant is ethylene-vinyl acetate or polyvinyl butyral.

11. The method of claim 9, wherein the second encapsulant is ionomer.

12. The method of claim 9, wherein the front substrate is glass or plastic.

13. The method of claim 9, wherein the back substrate is glass or plastic.
